(19) United States
(12) Patent Application Publication
(10) Pub. No.: US 2021/0272794 A1
(43) Pub. Date: Sep. 2, 2021

(54) Layered Material Laminate Structure and Method for Producing Same

(71) Applicant: Nippon Telegraph and Telephone Corporation, Tokyo (JP)

(72) Inventors: Koji Onomitsu, Tokyo (JP); Tetsuya Akasaka, Tokyo (JP); Masanobu Hiroki, Tokyo (JP); Junichi Nishinaka, Tokyo (JP); Kazuhide Kumakura, Tokyo (JP)

(21) Appl. No.: 17/256,941

(22) PCT Filed: Jun. 28, 2019
(86) PCT No.: PCT/JP2019/025826

§ 371 Date: Dec. 29, 2020

(30) Foreign Application Priority Data
Jul. 5, 2018 (JP) 2018-128027

(51) Int. Cl. H01L 21/02

(52) U.S. Cl. CPC H01L 21/022; H01L 21/02433; H01L 21/0254; H01L 21/02458

(57) ABSTRACT

First, in a first step, a semiconductor layer that is constituted by a nitride semiconductor and includes a group V polar surface as a main surface is formed. Next, in a second step, nitrogen atoms at the surface of the semiconductor layer are substituted with a group VI element that is any of oxygen, sulfur, selenium, and tellurium. Next, in a third step, a layered material layer is formed through epitaxial growth of a layered material on the semiconductor layer at which nitrogen atoms are substituted with the group VI element.

### CROSS-REFERENCE TO RELATED APPLICATIONS

This application is a national phase entry of PCT Application No. PCT/JP2019/025826, filed on Jun. 28, 2019, which claims priority to Japanese Application No. 2018-128027 filed on Jul. 5, 2018, which applications are hereby incorporated herein by reference.

### TECHNICAL FIELD

The present invention relates to a layered material laminate structure in which a layered material is layered on a nitride semiconductor, and a method for manufacturing the layered material laminate structure.

### BACKGROUND

A technology for orienting a transition metal dichalcogenide layered material and growing crystals thereof on a (111) surface of a group III-V compound semiconductor that has a zincblende structure has been proposed (see NPL 1). In this technology, a surface of a substrate is chemically inactivated by substituting group V elements such as As, Sb, and P at the surface of the above-described compound semiconductor with S, Se, and Te, which are group VI elements, and crystals of the transition metal dichalcogenide layered material, which is joined by van der Waals force, are grown on this surface.

Among layered materials such as transition metal dichalcogenide, most materials that serve as semiconductors have band gaps that are distributed in a range of 2.5 eV or less and largely overlap with the band gap of the group III-V compound semiconductor that serves as the substrate. Therefore, the materials are affected by band alignment with the substrate in the manufacture of a light emitting device or an electronic device, and have difficulty in exhibiting inherent characteristics.

In contrast, if a nitride semiconductor is used, the above-described problem regarding the band gap can be solved. Here, it is difficult to grow crystals on a (000-1) surface, which is a nitrogen surface of a nitride semiconductor having a hexagonal crystal structure, and the (000-1) surface is rarely used. In recent years, a technology has been proposed (see NPL 2) that makes it possible to obtain an extremely flat nitrogen surface of a nitride semiconductor by modulating a ratio between group V and group III at the surface in crystal growth with use of a flow-rate modulation epitaxy method (see PTL 1).

### CITATION LIST

### Patent Literature

[PTL 1] Japanese Patent Application Publication No. 561-275195

### Non Patent Literature

[NPL 1] A. Koma, “Van der Waals epitaxy for highly lattice-mismatched systems”, Journal of Crystal Growth, vol. 201/202, pp. 236-241, 1999.
[NPL 2] C. H. Lin et al., “N-face GaNd0001T films with hillock-free smooth surfaces grown by group-III-source flow-rate modulation epitaxy”, Japanese Journal of Applied Physics, vol. 55, 04EJ01, 2016.
[NPL 3] A. Yoshikawa et al., “Proposal and achievement of novel structure InN/GaN multiple quantum wells consisting of 1 ML and fractional monolayer InN wells inserted in GaN matrix”, Applied Physics Letters, vol. 90, 073101, 207.

### SUMMARY

### Technical Problem

Incidentally, nitrogen, which is a group V element on a nitrogen surface of GaN or AlN, is covalently bonded to a group III element via three back bonds, and the bond between nitrogen and gallium or between nitrogen and aluminum is extremely strong. Therefore, unlike arsenic and phosphorus in a GaAs substrate and an InP substrate that have the zincblende structure, it is considered that separating nitrogen is extremely difficult and substituting nitrogen with a group VI element is difficult.

Although the amount of overlap in the band gap with a layered material can be reduced with use of a nitride semiconductor, there is a problem in that it is difficult to form the layered material on the nitride semiconductor as described above.

Embodiments of the present invention were made to solve the above-described problem, and it is an object of embodiments of the present invention to make it possible to form a layered material on a nitride semiconductor.

### Means for Solving the Problem

A method for manufacturing a layered material laminate structure according to embodiments of the present invention includes a first step of forming a semiconductor layer that is constituted by a nitride semiconductor and includes a group V polar surface as a main surface, a second step of substituting nitrogen atoms at the surface of the semiconductor layer with a group VI element that is any of oxygen, sulfur, selenium, and tellurium, and a third step of forming a layered material layer through epitaxial growth of a layered material on the surface of the semiconductor layer at which nitrogen atoms are substituted with the group VI element.

The above-described method for manufacturing a layered material laminate structure may be performed as a method in which, in the first step, the semiconductor layer is formed and a surface layer that is constituted by a monomolecular layer of InN is formed on the surface of the semiconductor layer such that the surface layer includes a group V polar surface as a main surface, and in the second step, as the nitrogen atoms at the surface of the semiconductor layer, nitrogen atoms in the surface layer are substituted with the group VI element that is any of oxygen, sulfur, selenium, and tellurium.

In the above-described method for manufacturing a layered material laminate structure, in the second step, the nitrogen atoms at the surface of the semiconductor layer are substituted with the group VI element through heating.

The above-described method for manufacturing a layered material laminate structure may further include a fourth step of layering a different material layer that is constituted by at least one of a semiconductor layer and a metal layer on the layered material layer.

A layered material laminate structure according to embodiments of the present invention includes a semiconductor layer that is constituted by a nitride semiconductor and includes a group V polar surface as a main surface and a layered material layer that is constituted by a layered material formed on the semiconductor layer, wherein a group VI element that is any of oxygen, sulfur, selenium, and tellurium is bonded to the surface of the semiconductor layer, in place of nitrogen, and the layered material layer is formed on the surface of the semiconductor layer and bonded thereto by van der Waals force.

In the above-described layered material laminate structure, a surface layer that is constituted by a group VI element that is any of oxygen, sulfur, selenium, and tellurium and In may be formed on the surface of the semiconductor layer.

The above-described layered material laminate structure may further include a different material layer that is formed on the layered material layer and constituted by at least one of a semiconductor layer and a metal layer.

### Effects of Embodiments of the Invention

As described above, according to embodiments of the present invention, nitrogen atoms at the outermost surface of the semiconductor layer that is constituted by a nitride semiconductor and includes a group V polar surface as a main surface are substituted with a group VI element that is any of oxygen, sulfur, selenium, and tellurium, and therefore embodiments of the present invention have an excellent effect of facilitating the formation of a layered material on the nitride semiconductor.

### BRIEF DESCRIPTION OF THE DRAWINGS

FIG. 1 is a flow chart showing a method for manufacturing a layered material laminate structure in Embodiment 1 of the present invention.

FIG. 2 is a cross-sectional view showing a configuration of a layered material laminate structure in Embodiment 1 of the present invention.

FIG. 3 is a flow chart showing a method for manufacturing a layered material laminate structure in Embodiment 2 of the present invention.

FIG. 4 is a cross-sectional view showing a configuration of a layered material laminate structure in Embodiment 2 of the present invention.

FIG. 5 is a cross-sectional view showing a configuration of another layered material laminate structure in an embodiment of the present invention.

FIG. 6 is a cross-sectional view showing a configuration of another layered material laminate structure in an embodiment of the present invention.

FIG. 7 is a cross-sectional view showing a configuration of another layered material laminate structure in an embodiment of the present invention.

### DETAILED DESCRIPTION OF ILLUSTRATIVE EMBODIMENTS

The following describes methods for manufacturing a layered material laminate structure in embodiments of the present invention.

### Embodiment 1

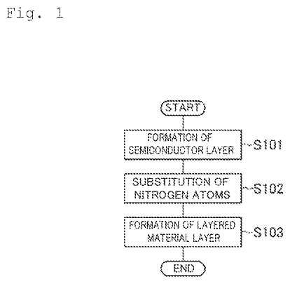

First, a method for manufacturing a layered material laminate structure in Embodiment 1 of the present invention will be described with reference to FIG. 1.

First, in a first step S101, a person who implements the embodiment forms a semiconductor layer that is constituted by a nitride semiconductor and includes a group V polar surface as a main surface. The semiconductor layer can be obtained by, for example, using a sapphire substrate, nitriding a surface of the sapphire substrate, and causing epitaxial growth of a nitride semiconductor, such as GaN or AlN, on the nitrided surface of the sapphire substrate through a well-known organometallic vapor phase growth method. Thus, the semiconductor layer including the group V polar surface as the main surface is obtained. Through the nitriding treatment, oxygen atoms at the main surface of the sapphire substrate are substituted with nitrogen to form AlN and make the main surface have the group V polarity (N polarity).

The person implementing the embodiment can nitride the main surface of the sapphire substrate by, for example, placing the sapphire substrate in a growth furnace of a predetermined organometallic vapor phase epitaxy apparatus or molecular beam epitaxy apparatus, supplying ammonia gas into the growth furnace, and heating the sapphire substrate to a predetermined temperature. Subsequently, crystals of GaN are grown along a c-axis on the sapphire substrate including the main surface of group V polarity, and thus the semiconductor layer constituted by GaN and including the group V polar surface as the main surface is obtained.

Next, in a second step S102, the person implementing the embodiment substitutes nitrogen atoms at the surface of the semiconductor layer with a group VI element that is any of oxygen, sulfur, selenium, and tellurium. If the semiconductor layer is heated to, for example, 1000° C. in an atmosphere of gas of the group VI element that is any of oxygen, sulfur, selenium, and tellurium, for example, nitrogen atoms at the surface of the semiconductor layer can be separated and substituted with the group VI element that is any of oxygen, sulfur, selenium, and tellurium. Note that oxygen plasma may also be used in the substitution with the group VI element.

Next, in a third step S103, the person implementing the embodiment forms a layered material layer through epitaxial growth of a layered material on the semiconductor layer at which nitrogen atoms are substituted with the above-described group VI element. It is possible to grow crystals of the layered material that is joined by van der Waals force on the semiconductor layer that is constituted by the nitride semiconductor and in which nitrogen at the outermost surface is substituted with the group VI element that is any of oxygen, sulfur, selenium, and tellurium.

Note that the layered material is constituted by a single two-dimensional unit layer or a plurality of two-dimensional unit layers that are layered on each other. Each unit layer is bonded in a two-dimensional direction via interatomic bonds such as covalent bonds or ion bonds, and unit layers that are adjacent to each other in the layered direction are bonded by van der Waals force.

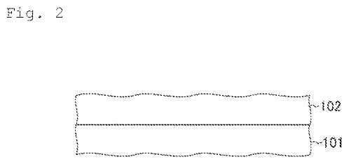

As shown in FIG. 2, a layered material laminate structure manufactured using the above-described manufacturing method includes a semiconductor layer 101 that is constituted by a nitride semiconductor and includes a group V polar surface as a main surface and a layered material layer 102 that is formed on the semiconductor layer 101. Note that the outermost surface of the semiconductor layer 101 is constituted by a group VI element that is any of oxygen, sulfur, selenium, and tellurium and a group III element, and the layered material layer 102 is formed on the outermost surface of the semiconductor layer 101 and bonded thereto by van der Waals force.

### Embodiment 2

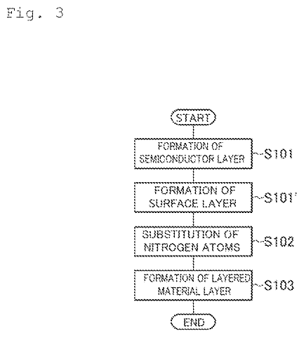

Next, a method for manufacturing a layered material laminate structure in Embodiment 2 of the present invention will be described with reference to FIG. 3.

First, in a first step S101, a person who implements the embodiment forms a semiconductor layer that is constituted by a nitride semiconductor and includes a group V polar surface as a main surface. The semiconductor layer including the group V polar surface as the main surface can be obtained by, for example, using a sapphire substrate, nitriding a surface of the sapphire substrate, and causing epitaxial growth of a nitride semiconductor, such as GaN or AlN, on the nitrided surface of the sapphire substrate through a well-known organometallic vapor phase growth method. Through the nitriding treatment, oxygen atoms at the main surface of the sapphire substrate are substituted with nitrogen to form AlN and make the main surface have the group V polarity (N polarity).

The first step S101 is the same as that in the above-described Embodiment 1. In Embodiment 2, a surface layer that is constituted by a monomolecular layer of InN is formed on the semiconductor layer in a supplemental first step S101′. The surface layer is formed in contact with the semiconductor layer. The surface layer is formed such that the surface layer includes a group V polar surface as a main surface.

The person implementing the embodiment forms the surface layer on the semiconductor layer by, for example, causing epitaxial growth of the monomolecular layer of InN through an organometallic vapor phase epitaxy method or a plasma-assisted molecular beam epitaxy method. Alternatively, the surface layer constituted by the monomolecular layer of InN can be formed by forming a multimolecular InN layer and heating the InN layer to decompose extra molecular layers.

Next, in a second step S102, the person implementing the embodiment substitutes nitrogen atoms in the surface layer with a group VI element that is any of oxygen, sulfur, selenium, and tellurium. If the surface layer is heated to, for example, 500° C. in an atmosphere of gas of the group VI element that is any of oxygen, sulfur, selenium, and tellurium, for example, nitrogen atoms in the surface layer can be separated and substituted with the group VI element that is any of oxygen, sulfur, selenium, and tellurium. Note that oxygen plasma may also be used for the substitution with the group VI element.

Nitrogen easily separates from a surface of InN, and the surface is roughened as a result of being heated (see NPL 3). However, as described in NPL 3, although this is the case of a group III polar surface, if a monomolecular layer of InN is formed, nitrogen easily separates when heated, but In does not separate until the temperature reaches the evaporation temperature of In. Therefore, in the technology described in NPL 3, a hetero-laminate structure that is constituted by different types of nitride semiconductors and includes an In layer that is kept flat is formed at a treatment temperature that is suitable for GaN. As described above, if the surface layer constituted by the monomolecular layer of InN is formed on the semiconductor layer, nitrogen can be substituted with the above-described group VI element at a lower temperature on the group V polar surface of the semiconductor layer.

Here, in a state in which the surface layer constituted by InN is absent, heating needs to be performed at at least 1000° C. to separate nitrogen atoms at the main surface of the semiconductor layer and substitute the nitrogen atoms with a group VI element, but in such a case, the surface may be roughened and a range of conditions under which a flat surface can be obtained is extremely small. In contrast, if the surface layer constituted by the monomolecular layer of InN is provided, nitrogen atoms at the surface can be substituted with the group VI element at a lower temperature, the surface can be kept from being roughened, and a flat surface can be more easily obtained. Note that if the semiconductor layer is constituted by InN, the surface layer is unnecessary.

Next, in a third step S103, the person implementing the embodiment forms a layered material layer by causing epitaxial growth of a layered material on the semiconductor layer (surface layer) at which nitrogen atoms are substituted with the above-described group VI element. The surface layer at which nitrogen atoms are substituted with the above-described group VI element is a layer of the nitride semiconductor in which nitrogen at the outermost surface is substituted with the group VI element that is any of oxygen, sulfur, selenium, and tellurium, and crystals of the layered material joined by van der Waals force can grow on the surface layer.

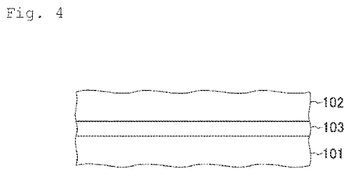

As shown in FIG. 4, a layered material laminate structure that is manufactured using the above-described manufacturing method includes a semiconductor layer 101 that is constituted by a nitride semiconductor and includes a group V polar surface as a main surface, a monomolecular surface layer 103 that is formed in contact with the semiconductor layer 101, and a layered material layer 102 that is formed on the surface layer 103. Note that the surface layer 103 is constituted by indium and the group VI element that is any of oxygen, sulfur, selenium, and tellurium, and the layered material layer 102 formed on the surface layer 103 is bonded to the surface layer 103 by van der Waals force.

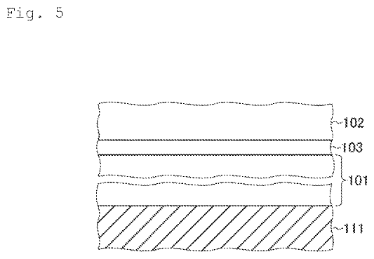

Note that if the semiconductor layer is formed on a sapphire substrate, the layered material laminate structure includes the semiconductor layer 101 that is formed on a sapphire substrate 11, the surface layer 103 that is formed in contact with the semiconductor layer 101, and the layered material layer 102 that is formed on the surface layer 103 as shown in FIG. 5.

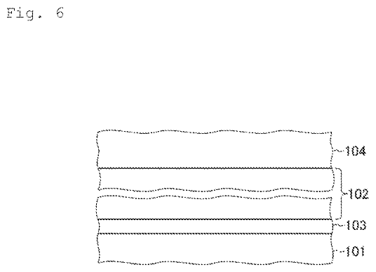

Alternatively, as shown in FIG. 6, the layered material laminate structure may also be a hetero structure in which a layered material layer 104 that is constituted by a layered material of a different type is layered on the layered material layer 102 and joined to the layered material layer 102 by van der Waals force.

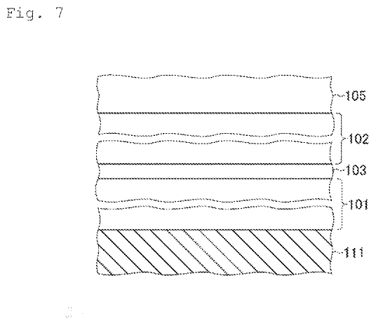

Also, in a fourth step after the above-described third step, the person implementing the embodiment may also form a different material layer 105 that is constituted by semiconductor crystals or metal crystals on the layered material layer 102 as shown in FIG. 7 by layering the different material layer constituted by at least one of a semiconductor layer and a metal layer on the layered material layer. Crystallinity of the different material layer 105 may be inferior to crystallinity of a layer that is formed through epitaxial growth using three-dimensional crystals as a substrate. However, layers constituting the layered material layer 102 are bonded by van der Waals force, and therefore the different material layer 105 can be mechanically separated from the sapphire substrate 11 at the layered material layer 102.

The layered material laminate structures in the above-described embodiments can be applied to active elements such as transistors, for example. For example, a person who implements the embodiments forms semiconductor layers constituted by a first semiconductor layer that is made of an electrically conductive nitride semiconductor and a second semiconductor layer that is formed on the first semiconductor layer using undoped AlN, GaN, h-BN, or the like, and forms a layered material layer on the semiconductor layers. With this configuration, a back-gate field effect transistor can be obtained with the first semiconductor layer serving as a back gate, the second semiconductor layer serving as a gate insulating layer, and the layered material layer serving as a channel layer.

If semiconductor layers are constituted by a p-type semiconductor layer that is made of a p-type nitride semiconductor and an n-type semiconductor layer that is formed on the p-type semiconductor layer using an n-type nitride semiconductor, and a hetero structure constituted by a p-type layered material layer and an n-type layered material layer is formed on the semiconductor layers, the thus manufactured element can operate as a tandem type solar cell or a photodiode. In this configuration, light absorbed by the layered material layers passes through the nitride semiconductors, and therefore light can be taken from the nitride semiconductor layer side. A photodiode configured as described above has advantages in that the absorption wavelength can be varied by changing materials of the layered material layers and the diode can be constituted by nitrides that can withstand high voltage. Furthermore, a layered material portion can be sealed by coating the growth surface side. In a case in which a chalcopyrite semiconductor layer is formed on the layered material layer as well, the element can operate as a tandem type solar cell.

As described above, according to embodiments of the present invention, nitrogen atoms at the outermost surface of the semiconductor layer that is constituted by a nitride semiconductor and includes a group V polar surface as a main surface are substituted with a group VI element that is any of oxygen, sulfur, selenium, and tellurium, and therefore the layered material can be more easily formed on the nitride semiconductor.

Note that the present invention is not limited to the above-described embodiments, and it is apparent that many modifications and combinations can be made within the technical idea of the present invention by a person having ordinary skill in the art.

### REFERENCE SIGNS LIST

101 Semiconductor layer
102 Layered material layer
103 Surface layer
104 Layered material layer
105 Different material layer

1.-7. (canceled)

8. A method for manufacturing a layered material laminate structure, the method comprising:
a first step of forming a semiconductor layer comprising a nitride semiconductor and including a group V polar surface as a main surface;
a second step of substituting nitrogen atoms at the main surface of the semiconductor layer with a group VI element that is oxygen, sulfur, selenium, or tellurium; and
a third step of forming a layered material layer through epitaxial growth of a layered material on the main surface of the semiconductor layer at which the nitrogen atoms are substituted with the group VI element.

9. The method according to claim 8, wherein, in the first step, the semiconductor layer is formed and a surface layer comprising a monomolecular layer of InN is formed on the main surface of the semiconductor layer such that the surface layer includes the group V polar surface as a main surface, and in the second step, as the nitrogen atoms at the main surface of the semiconductor layer are substituted, nitrogen atoms in the surface layer are substituted with the group VI element.

10. The method according to claim 8, wherein, in the second step, the nitrogen atoms at the main surface of the semiconductor layer are substituted with the group VI element through heating.

11. The method according to claim 8, further comprising a fourth step of layering a different material layer comprising at least one of an additional semiconductor layer or a metal layer on the layered material layer.

12. A layered material laminate structure comprising:
a semiconductor layer comprising a nitride semiconductor and including a group V polar surface as a main surface; and
a layered material layer comprising a layered material on the semiconductor layer, wherein a group VI element that is oxygen, sulfur, selenium, or tellurium is bonded to the main surface of the semiconductor layer, in place of nitrogen, and the layered material layer is on the main surface of the semiconductor layer and bonded thereto by van der Waals force.

13. The layered material laminate structure according to claim 12, wherein a surface layer comprising the group VI element and indium is formed on the main surface of the semiconductor layer.

14. The layered material laminate structure according to claim 12, further comprising a different material layer on the layered material layer, the different material layer comprising at least one of an additional semiconductor layer or a metal layer.

15. A method for manufacturing a layered material laminate structure, the method comprising:
forming a semiconductor layer comprising a nitride semiconductor and including a group V polar surface as a first main surface;
forming a surface layer comprising a monomolecular layer of InN on the first main surface of the semiconductor layer such that the surface layer includes the group V polar surface as a second main surface;
substituting nitrogen atoms at the second main surface of the surface layer with a group VI element that is any of oxygen, sulfur, selenium, or tellurium; and
forming a layered material layer through epitaxial growth of a layered material on the second main surface of the surface layer at which the nitrogen atoms are substituted with the group VI element.

16. The method according to claim 15, wherein, substituting the nitrogen atoms at the second main surface of the surface layer with the group VI element comprises a heating process.

17. The method according to claim 15, further comprising layering a different material layer comprising at least one of an additional semiconductor layer or a metal layer on the layered material layer.

18. The method according to claim 15, wherein the semiconductor layer is formed on a sapphire substrate.
